(19) United States
(12) Patent Application Publication
(10) Pub. No.: US 2026/0231732 A1
(43) Pub. Date: Aug. 6, 2026

(54) Semiconductor Device Measurement Method and Semiconductor Device Measurement Apparatus

(71) Applicant: Hitachi High-Tech Corporation, Minato-ku, Tokyo (JP)

(72) Inventors: Toshimasa KAMEDA, Tokyo (JP); Satoshi SAKAI, Tokyo (JP); Maki KIMURA, Tokyo (JP); Miki AOYAGI, Tokyo (JP)

(21) Appl. No.: 19/150,942

(22) PCT Filed: Mar. 1, 2023
(86) PCT No.: PCT/JP2023/007487

§ 371 Date: Jul. 25, 2025

(51) Int. Cl. H10P 74/20; G01N 23/2251

(52) U.S. Cl. CPC H10P 74/203; G01N 23/2251; G01N 2223/305

(57) ABSTRACT

This semiconductor device measurement method comprises: preparing model data 5 representing a semiconductor device 2, in which a first parameter 51 representing a characteristic of a lower layer structure 22 is known; preparing a plurality of measurement conditions A-C for a measurement device 3; performing a simulation per each of the plurality of measurement conditions using the model data 5, and acquiring simulation results (images A-C) including at least one among an image or a signal waveform obtained when the semiconductor device represented by the model data 5 is irradiated with a charged particle beam; and comparing the first parameter 51 and a plurality of second parameters A-C, corresponding to characteristics of the lower layer structure, derived from each of the plurality of simulation results, and presenting a recommended measurement condition, from among the plurality of measurement conditions, which is recommended for measuring the semiconductor device.

### TECHNICAL FIELD

The present disclosure relates to a semiconductor device measurement method and a semiconductor device measurement apparatus.

### BACKGROUND ART

In recent years, a semiconductor device having a gate all around (GAA) structure in which the entire periphery of a wire-shaped or sheet-shaped channel is covered with a gate has become mainstream (for example, see PTL 1). The GAA structure is formed by forming a stacked structure of a single crystal silicon germanium (SiGe) layer and a single crystal silicon (Si) layer on a single crystal silicon (Si) substrate and then removing the SiGe layer by etching (see FIG. 4A, FIG. 4B, paragraph 0022, and the like in PTL 1).

In performance evaluation of a semiconductor device having the GAA structure, it is particularly important to monitor a retreat amount (a recess quantity) of the SiGe layer.

### CITATION LIST

### Patent Literature

PTL 1: JP2022-027614A

### SUMMARY OF INVENTION

### Technical Problem

On the other hand, since a critical dimension-scanning electron microscope (a CD-SEM) used for measurement of a semiconductor device is generally used to observe and measure a sample from above, a recess quantity of the SiGe layer cannot be directly observed and measured.

Therefore, it is difficult to optimize a measurement condition (an acceleration voltage, a focus, beam tilt, a detector position, and the like) for measuring a parameter (for example, a recess quantity of a SiGe layer) of a lower layer structure that cannot be directly observed and measured due to an upper structure.

An object of the present disclosure is to provide a semiconductor device measurement method and a semiconductor device measurement system capable of optimizing a measurement condition for measuring a parameter of a lower layer structure that cannot be directly observed and measured due to an upper structure.

### Solution to Problem

A semiconductor device measurement method according to the present disclosure is a measurement method for a semiconductor device e including an upper layer structure constituting a part of the semiconductor device and a lower layer structure located below the upper layer structure. The semiconductor device measurement method includes: preparing model data that indicates the semiconductor device and in which a first parameter indicating a feature of the lower layer structure is known; preparing a plurality of measurement conditions for a measurement apparatus that irradiates the semiconductor device with a charged particle beam to measure the semiconductor device; performing simulation using the model data under each of the plurality of measurement conditions and acquiring a simulation result including at least one of an image or a signal waveform obtained when the semiconductor device represented by the model data is irradiated with the charged particle beam; comparing the first parameter with each of a plurality of second parameters corresponding to features of the lower layer structure, the second parameters being respectively derived from a plurality of the simulation results; and presenting a recommended measurement condition recommended for measuring the semiconductor device from among the plurality of measurement conditions based on comparison results between the first parameter and the second parameters.

A measurement system according to the present disclosure is a measurement system for measuring a semiconductor device including an upper layer structure constituting a part of the semiconductor device and a lower layer structure located below the upper layer structure. The measurement system includes: a measurement apparatus configured to irradiate the semiconductor device with a charged particle beam to measure the semiconductor device; and a computer system including a processor and a memory. The computer system is configured to store model data that indicates the semiconductor device and in which a first parameter indicating a feature of the lower layer structure is known, store a plurality of measurement conditions for the measurement apparatus, perform simulation using the model data under each of the plurality of measurement conditions and acquire a simulation result including at least one of an image or a signal waveform obtained when the semiconductor device represented by the model data is irradiated with the charged particle beam, compare the first parameter with each of a plurality of second parameters corresponding to features of the lower layer structure, the second parameters being respectively derived from a plurality of the simulation results, and present a recommended measurement condition recommended for measuring the semiconductor device from among the plurality of measurement conditions based on comparison results between the first parameter and the second parameters.

A semiconductor device measurement method according to the present disclosure is a measurement method for a semiconductor device including an upper layer structure constituting a part of the semiconductor device and a lower layer structure located below the upper layer structure. The semiconductor device measurement method includes: preparing a plurality of measurement conditions for a measurement apparatus that irradiates the semiconductor device with a charged particle beam to measure the semiconductor device; acquiring a measurement result for each of the plurality measurement conditions by irradiating a sample of the semiconductor device with a charged particle beam, the measurement result including at least one of an image or a signal waveform of the sample; measuring a cross section of the sample and acquiring a first parameter indicating a feature of the lower layer structure; comparing the first parameter with each of a plurality of second parameters corresponding to features of the lower layer structure, the second parameters being respectively derived from a plurality of the measurement results; and presenting a recommended measurement condition recommended for measuring the semiconductor device from among the plurality of measurement conditions based on comparison results between the first parameter and the second parameters.

A measurement system according to the present disclosure is a measurement system for a semiconductor device including an upper layer structure constituting a part of the semiconductor device and a lower layer structure located below the upper layer structure. The measurement system includes a measurement apparatus configured to irradiate the semiconductor device with a charged particle beam to measure the semiconductor device; a processing apparatus configured to process the semiconductor device; and a computer system including a processor and a memory. The measurement apparatus is configured to store a plurality of measurement conditions for the measurement apparatus, and acquire a measurement result for each of the plurality of measurement conditions by irradiating a sample of the semiconductor device with the charged particle beam, the measurement result including at least one of an image or a signal waveform of the sample. The processing apparatus is configured to process the sample to expose a cross section of the sample. The computer system is configured to compare a first parameter indicating a feature of the lower layer structure obtained from a cross section measurement result obtained by measuring the cross section of the sample with each of a plurality of second parameters corresponding to features of the lower layer structure, the second parameters being respectively derived from the plurality of measurement results, and present a recommended measurement condition recommended for measuring the semiconductor device from among the plurality of measurement conditions based on comparison results between the first parameter and the second parameters.

### Advantageous Effects of Invention

According to the present disclosure, it is possible to optimize a measurement condition for measuring a parameter of a lower layer structure that cannot be directly observed or measured due to an upper structure.

Other technical problems and novel features will become apparent from description of the present description and the accompanying drawings.

### BRIEF DESCRIPTION OF DRAWINGS

FIG. 1 is a diagram illustrating an outline of a measurement system 1 for a semiconductor device 2 and a measurement method for the semiconductor device 2 according to Embodiment 1.

FIG. 2 is a diagram illustrating an example of the measurement system 1.

FIG. 3 is a diagram illustrating an example of a scanning electron microscope (a measurement apparatus 103) such as a CD-SEM. FIG. 4 is a block diagram illustrating a hardware structure of a simulator 105.

FIG. 5 is a flow chart illustrating a method for manufacturing a semiconductor device including a GAA structure and a method for removing an upper structure performed before measurement of the semiconductor device.

FIG. 6 is a diagram illustrating a change in a cross section of a product in a manufacturing process of the semiconductor device.

FIG. 7 is a diagram illustrating a change in a cross section of a product in a manufacturing process of the semiconductor device.

FIG. 8 is a diagram illustrating a change in the cross section of the product in the manufacturing process of the semiconductor device.

FIG. 9 is a diagram illustrating details of recess quantities.

FIG. 10 is a schematic view illustrating an electron microscope image 1000 of a Si and SiGe stacked layer 604.

FIG. 11 is an example of a flow chart for presenting a measurement condition recommended for use in a measurement apparatus when a recess is measured.

FIG. 12 illustrates an example of model data used for simulation.

FIG. 13 is a graph illustrating a relationship between a parameter (a recess quantity of a SiGe layer) of model data used for simulation and measurement values obtained by measuring an image created based on the simulation.

FIG. 14 is a diagram illustrating an outline of a measurement system 1401 for the semiconductor device 2 and a measurement method for the semiconductor device 2 according to Embodiment 1.

FIG. 15 is a flow chart illustrating a step of selecting an appropriate measurement condition using a plurality of GAA structures having different recess quantities that are actually generated under a plurality of etching conditions without using simulation or the like.

### DESCRIPTION OF EMBODIMENTS

In the following embodiments, for the sake of convenience, the description may be made by being divided into a plurality of sections or embodiments, but unless otherwise stated, they are not unrelated to one another, and one has a relation with all or a part of modifications, details, supplementary explanations, and the like of the other.

In the following embodiments, when referring to the number of elements (including the number, a numerical value, an amount, a range, or the like) or the like, the number of elements is not limited to a specific number, and may be the specific number or more or the specific number or less, unless otherwise specified or except a case where the number is apparently limited to a specific number in principle.

Further, in the following embodiments, it is needless to mention that components (also including element steps and the like) are not necessarily essential unless otherwise specified or unless clearly considered to be essential in principle.

Similarly, in the following embodiments, when referring to a shape, a positional relation, or the like of a component or the like, the shape or the like is substantially approximate or similar to the shape or the like unless otherwise specified or clearly considered otherwise in principle. The same applies to the above-described numerical value and range.

In all drawings for describing the embodiments, the same members are denoted by the same reference numerals in principle, and repeated description thereof will be omitted.

### Embodiment 1

### Outline of Measurement System 1 for Semiconductor Device 2 and Measurement Method for Semiconductor Device 2

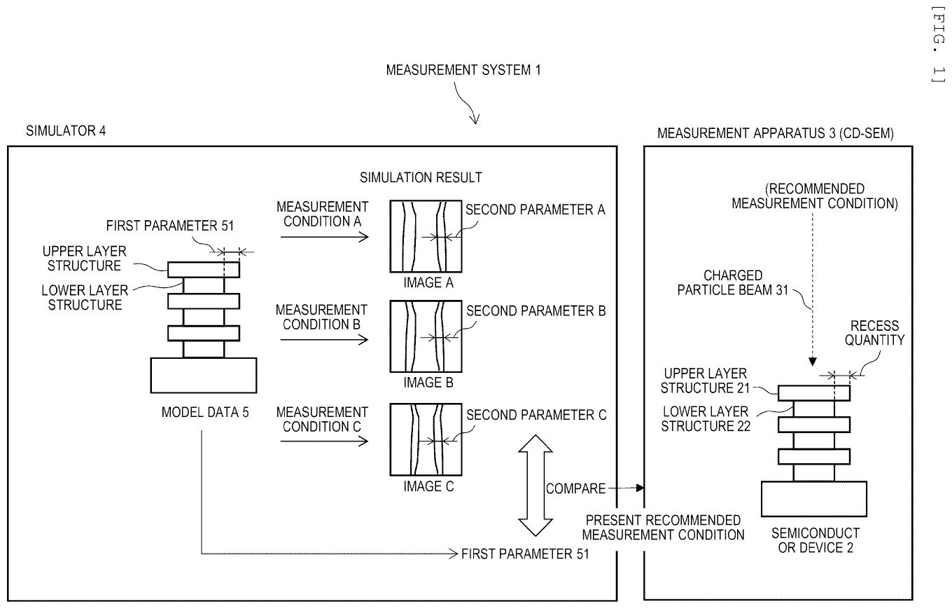

First, an outline of a measurement system 1 for a semiconductor device 2 and a measurement method for the semiconductor device 2 according to Embodiment 1 will be described with reference to FIG. 1. The semiconductor device 2 to be measured includes an upper layer structure 21 that constitutes a part of the semiconductor device 2 and a lower layer structure 22 located below the upper layer structure 21. For example, the semiconductor device 2 is a Si-SiGe stacked layer in which the upper layer structure 21 is a Si layer and the lower layer structure 22 is a SiGe layer.

The measurement system 1 includes a measurement apparatus 3 (for example, a CD-SEM) that irradiates the semiconductor device 2 with a charged particle beam 31 to measure the semiconductor device 2, and a simulator 4 that presents a measurement condition recommended for the measurement apparatus 3 to measure the semiconductor device 2 (hereinafter, referred to as a recommended measurement condition).

First, one or more pieces of model data 5 required for performing simulation by the simulator 4 are prepared. The model data 5 includes information indicating a shape, a size, a material, and the like of the semiconductor device 2, and particularly includes a first parameter 51 corresponding to a recess quantity of the lower layer structure 22 of the semiconductor device 2.

A plurality of measurement conditions (for example, measurement conditions A to C) used for the measurement apparatus 3 to measure the semiconductor device 2 are prepared. These measurement conditions may be measurement conditions set by a skilled laboratory technician or the like based on past experience, or may be measurement conditions acquired or created based on measurement history of the measurement apparatus 3.

Then, the simulator 4 performs simulation using the model data 5 under each of the plurality of measurement conditions (for example, the measurement conditions A to C), and acquires simulation results (for example, images A to C) including at least one of an image or a signal waveform obtained when a semiconductor device represented by the model data 5 is irradiated with a charged particle beam.

The simulator 4 calculates a plurality of second parameters (second parameters A to C) indicating feature values (for example, recess quantities) of the lower layer structure 22 based on the plurality of simulation results (images A to C). Then, the simulator 4 compares the first parameter 51 with the second parameters (the second parameters A to C), and presents a recommended measurement condition recommended for the measurement of the semiconductor device 2 from the plurality of measurement conditions. For example, when the second parameter B is closest to the first parameter 51 among the second parameters A to C, the measurement condition B is presented to the measurement apparatus 3 as the recommended measurement condition.

Then, the measurement apparatus 3 irradiates the semiconductor device 2 with the charged particle beam 31 according to the recommended measurement condition, acquires an image or a signal waveform, and calculates a feature value (for example, a recess quantity) of the lower layer structure 22 based on the image or the signal waveform.

Hereinafter, details of the measurement system 1 according to Embodiment 1 will be described.

### Measurement System 1

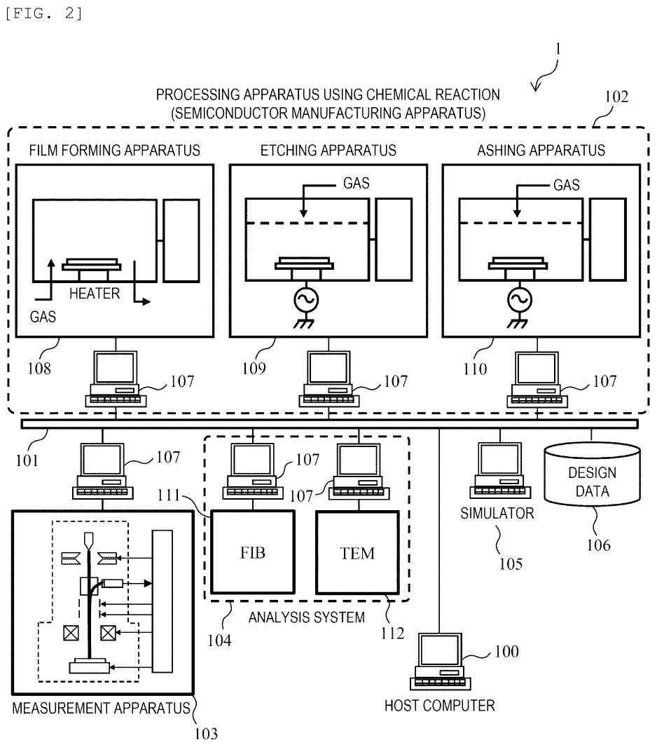

FIG. 2 is a diagram illustrating an example of the measurement system 1. The measurement system 1 illustrated in FIG. 2 is used to appropriately evaluate a recess quantity of a SiGe layer (lower layer structure) having, for example, a gate all around (GAA) structure. The measurement system 1 mainly includes a host computer 100, a semiconductor manufacturing apparatus 102, a measurement apparatus 103 (the measurement apparatus 3 (FIG. 1) ), an analysis system 104, a simulator 105 (the simulator 4 (FIG. 1)), and a design data storage medium 106. The host computer 100 is communicably connected to, for example, the semiconductor manufacturing apparatus 102, the measurement apparatus 103, the analysis system 104, the simulator 105, and the design data storage medium 106 via a network 101.

### Host Computer 100

The host computer 100 is configured to operate each apparatus via a computer system 107 provided in each connected apparatus and process information obtained by each apparatus. Although the host computer 100 and the computer system 107 that executes control and the like of each apparatus are separately provided in the measurement system 1 illustrated in FIG. 2, the host computer 100 and at least one computer system 107 may be integrated. Although each apparatus and the computer system 107 connected to each apparatus are separately provided, the apparatus and the computer system 107 provided for the apparatus may be integrated.

### Processing Apparatus Using Chemical Reaction (Semiconductor Manufacturing Apparatus 102)

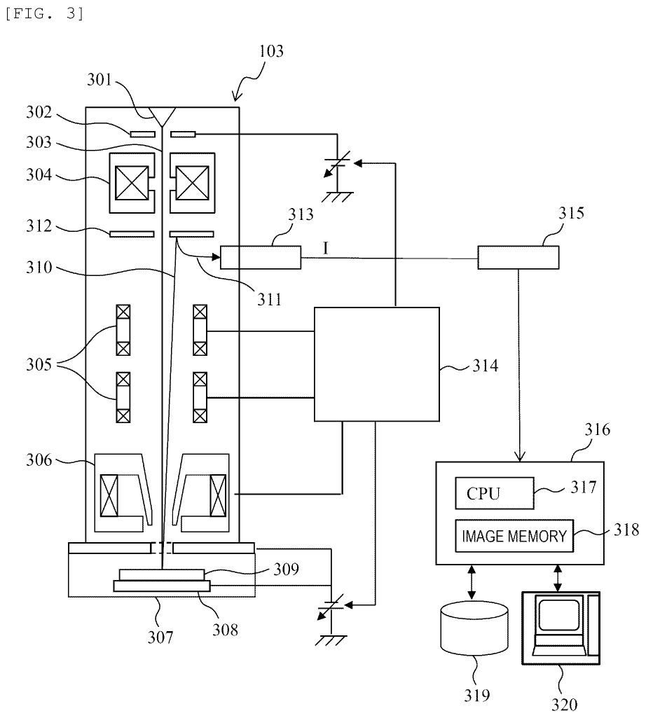

The measurement system 1 illustrated in FIG. 2 includes an apparatus (a processing apparatus (a semiconductor manufacturing apparatus 102) that uses a chemical reaction) for removing an upper structure (for example, a dummy gate stacked body (FIGS. 3A and 3B in PTL 1)) that hinders arrival of a charged particle beam such as an electron beam or light in order to appropriately evaluate a recess quantity of the SiGe layer of the GAA structure. The dummy gate stacked body that is an example of an upper structure portion is a dummy gate stacked body that is removed in subsequent processing and is replaced with a final gate stacked body.

A recess of the SiGe layer (a lower layer structure) of the GAA structure is formed by etching or the like after the upper structure is formed. Therefore, when the recess of the SiGe layer is formed, the upper structure that hinders the arrival of the charged particle beam was already formed above the SiGe layer. Therefore, it is desirable to perform measurement or inspection for evaluating the recess of the lower layer structure after removing the upper structure. In the present embodiment, a semiconductor device from which the upper structure was removed is a measurement target, but semiconductor device in which the upper structure remains may also be a measurement target.

The measurement system 1 illustrated in FIG. 2 includes a film forming apparatus 108, an etching apparatus 109, and an ashing apparatus 110 as processing apparatuses (the semiconductor manufacturing apparatus 102) that use a chemical reaction.

### Film Forming Apparatus 108

The film forming apparatus 108 is used to fill a mask layer. The film forming apparatus 108 is an apparatus capable of forming a mask layer on a substrate, such as an atomic layer deposition (ALD) apparatus or a chemical vapor deposition (CVD) apparatus. The computer system 107 connected to the film forming apparatus 108 controls the film forming apparatus 108 to execute film forming processing according to a recipe (an operation program) registered in advance.

### Etching Apparatus 109

The etching apparatus 109 is an apparatus that chemically corrodes or etches a shape of a thin film using a chemical reaction of a chemical solution, a reaction gas, or ions. In the present embodiment, the etching apparatus 109 is used to remove the upper structure that hinders the arrival of the electron beam to a Si and SiGe stacked layer after the mask layer is filled. Similar to the computer system 107 connected to the film forming apparatus 108, the computer system 107 connected to the etching apparatus 109 controls the etching apparatus 109 to execute removing processing according to a recipe (an operation program) registered in advance.

### Ashing Apparatus 110

The ashing apparatus 110 is an apparatus for peeling off a resist or the like, and is an apparatus for removing the resist or the like by converting the resist or the like into a gas by, for example, chemically reacting a plasma-activated gas with the resist. In present embodiment, the ashing apparatus 110 is mainly used for removing a spacer. Similar to the computer system 107 connected to the film forming apparatus 108, the computer system 107 connected to the ashing apparatus 110 controls the ashing apparatus 110 to execute removing processing according to a recipe (an operation program) registered in advance.

### Measurement Apparatus 103

The measurement system 1 illustrated in FIG. 2 further includes the measurement apparatus 103. The measurement apparatus 103 is, for example, a critical dimension scanning electron microscope (a CD-SEM), and measures a recess quantity or the like of a SiGe layer based on irradiation on the Si and SiGe stacked layer with a beam after an upper structure on the Si and SiGe stacked layer is removed. The definition of the recess quantity will be described later.

FIG. 3 is a diagram illustrating an example of the scanning electron microscope (the measurement apparatus 103) such as a CD-SEM. An electron beam 303 (the charged particle beam 31) extracted from an electron source 301 by an extraction electrode 302 is accelerated by an acceleration electrode (not illustrated). The accelerated electron beam 303 is focused by a condenser lens 304 which is a form of a focus lens, and then deflected by a scanning deflector 305. Accordingly, a sample 309 (for example, the semiconductor device 2 (FIG. 1)) is one-dimensionally or two-dimensionally scanned with the electron beam 303. The electron beam 303 incident on the sample 309 is decelerated by a deceleration electric field formed by applying a negative voltage to an electrode built in a sample stage 308, and is focused by a lens action of an objective lens 306, and then is emitted to a surface of the sample 309. An inner side of a sample chamber 307 is maintained in vacuum.

Electrons 310 (secondary electrons, backscattered electrons, and the like) are emitted from an irradiation portion on the sample 309. The emitted electrons 310 are accelerated in a direction of the electron source 301 by an acceleration action based on the negative voltage applied to the electrode built in the sample stage 308. The accelerated electrons 310 collide with a conversion electrode 312 to generate secondary electrons 311. The secondary electrons 311 emitted from the conversion electrode 312 are detected by a detector 313, and an output I of the detector 313 changes according to an amount of captured secondary electrons. Brightness of an image changes according to the change in the output I. For example, when a two-dimensional image is formed, a deflection signal to the scanning deflector 305 and the output I of the detector 313 are synchronized to form an image of a scanning region.

The CD-SEM (the measurement apparatus 103) illustrated in FIG. 3 indicates an example in which the electrons 310 emitted from the sample 309 are converted into the secondary electrons 311 at one end in the conversion electrode 312 and are detected, but it is needless to say that the present disclosure is not limited to such a configuration, and for example, a configuration in which a detection surface of an electron multiplier tube or a detector is disposed on a trajectory of accelerated electrons may be adopted. A control device 314 supplies a necessary control signal to each optical element of the CD-SEM according to an operation program for controlling the CD-SEM, which is referred to as an imaging recipe.

Next, a signal detected by the detector 313 is converted into a digital signal by an A/D converter 315 and sent to an image processing unit 316. The image processing unit 316 creates an integrated image by integrating signals obtained by a plurality of times of scanning in units of frames.

Here, an image obtained by one scanning of a scanning region is referred to as an image of one frame. For example, when images of eight frames are integrated, an integrated image is generated by performing summed averaging processing on signals obtained by eight times two-dimensional scanning in units of pixels. A plurality of images of one frame can be created and stored for each scanning by scanning the same scanning region a plurality of times.

Further, the image processing unit 316 includes an image memory 318 that is an image storage medium for temporarily storing a digital image, and a CPU 317 that calculates a feature value (a dimension value of a width of a line or a hole, a roughness index value, an index value indicating a pattern shape, an area value of a pattern, a pixel position which is an edge position, and the like) from an image stored in the image memory 318. In the present embodiment, for example, the CPU 317 calculates a recess quantity of the SiGe layer of the GAA structure of the semiconductor device 2.

The measurement apparatus 103 further includes a storage medium 319 that stores measurement values of respective patterns, luminance values of respective pixels, and the like. The overall control can be implemented by a graphical user interface (hereinafter, referred to as a GUI) for an operation of a necessary apparatus, confirmation of a detection result, and the like, which are performed by a workstation 320. The image memory 318 stores an output signal of the detector 313 (a signal in proportion to an amount of electrons emitted from a sample) at a corresponding address (x, y) in the memory in synchronization with a scanning signal supplied to the scanning deflector 305. The image processing unit 316 also functions as a calculation processing apparatus that creates a line profile based on luminance values stored in the memory, specifies an edge position using a threshold method or the like, and measures a dimension between edges.

Instead of the workstation 320 and the image processing unit 316, the computer system 107 and the host computer 100 illustrated in FIG. 2 may be used to perform necessary control and calculation processing.

### Analysis System 104

The measurement system 1 illustrated in FIG. 2 includes the analysis system 104. The analysis system 104 includes a focused ion beam (FIB) apparatus 111 and a transmission electron microscope (TEM) 112. The FIB apparatus 111 is an apparatus that processes a sample by irradiating the sample with an ion beam emitted from a liquid metal ion source such as gallium. A portion of the sample irradiated with the beam is sputtered, and desired processing such as drilling can be performed. The TEM 112 is an apparatus that irradiates a thinned sample with an electron beam and forms an enlarged image of the sample by imaging electrons transmitted through the sample. For example, based on position information input from the host computer 100 or the computer system 107, the FIB apparatus 111 executes cross section processing at a desired position of the sample, and further executes processing to thin an exposed cross sectional portion. The TEM 112 is used to measure the thinned sample and measure, for example, a recess quantity of a SiGe layer based on an observation image of the sample.

### Simulator 105

The simulator 105 (the simulator 4 (FIG. 1)) estimates an image or a signal profile indicating an intensity distribution of secondary electrons or backscattered electrons by simulation. Specifically, a generation process of the secondary electrons generated by the charged particle beam incident on the sample and the backscattered electrons emitted from the sample is reproduced using random numbers, and an emission angle, energy, and the like of the secondary electrons and the backscattered electrons are calculated by performing repeated calculation. Monte Carlo simulation or the like is used in the calculation.

The simulator 105 reads one or more pieces of the model data 5 from the design data storage medium 106. The model data 5 includes information on a shape and a composition of a pattern and the like included in the semiconductor device 2, and the first parameter 51 corresponding to a feature value (for example, a recess quantity) of the lower layer structure (for example, the SiGe layer) is known information. The simulator 105 is configured to estimate an electron microscope image (for example, the images A to C (FIG. 1)) based on the model data 5 and a measurement condition of the measurement apparatus 103 including structure information of the measurement apparatus 103 such as a position (a position with respect to a beam irradiation point) of the detector 313 in the measurement apparatus 103 and a beam irradiation condition, which are stored in advance.

In the simulation, an image, luminance information, a profile, and the like may be derived using not only a trajectory calculation method such as Monte Carlo simulation but also layout data (including three-dimensional data such as a film thickness), a coefficient that changes depending on a material, a measurement condition of an electron microscope, and the like, and a model that defines a relationship between luminance information and the like. In addition, image data and the like may be estimated by inputting known information to a learning device that has been trained using a data set of a measurement condition of an electron microscope, material information, 3D layout information, and luminance information and the like (image data, profile, and the like) as labeled training data.

### Hardware Configuration of Simulator 105

FIG. 4 is a block diagram illustrating a hardware structure example of the simulator 105. The simulator 105 includes a processor 401, a main storage unit 402, an auxiliary storage unit 403, and an input and output interface (I/F) 404. The processor 401 is a central processing unit that performs various calculations. The processor 401 is, for example, a central processing unit (CPU), a digital signal processor (DSP), or an application specific integrated circuit (ASIC). The main storage unit 402 stores a program to be executed by the processor 401, data required for executing the program, and the like. The main storage unit 402 is, for example, a random access memory (RAM) and a flash memory. The auxiliary storage unit 403 stores various programs and various kinds of data. The auxiliary storage unit 403 stores, for example, an operating system (OS), various programs, and various kinds of data required for executing the programs. The auxiliary storage unit 403 is a solid state drive (SSD) device, a hard disk drive (HDD) device, or the like. The input and output I/F 404 is a device controller communicably connected to a keyboard, a mouse, a display, and the like, a network controller communicably connected to a network, and the like.

The processor 401 loads a program (for example, simulation software) stored in the auxiliary storage unit 403 into a work area of the main storage unit 402 in an executable manner. For example, the processor 401 executes the simulation software loaded into the main storage unit 402, and outputs simulation results (images A to C) using the model data 5 and the plurality of measurement conditions A and B. Then, the processor 401 calculates the second parameters A to C based on the simulation results (images A to C), and compares the first parameter with the second parameters A to C. Then, the processor 401 presents a recommended measurement condition recommended for the measurement apparatus 103 to measure the semiconductor device 2 by displaying the recommended measurement condition on a display unit based on a comparison result.

### Method for Manufacturing Semiconductor Device

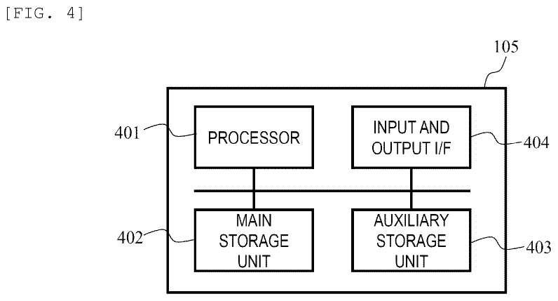

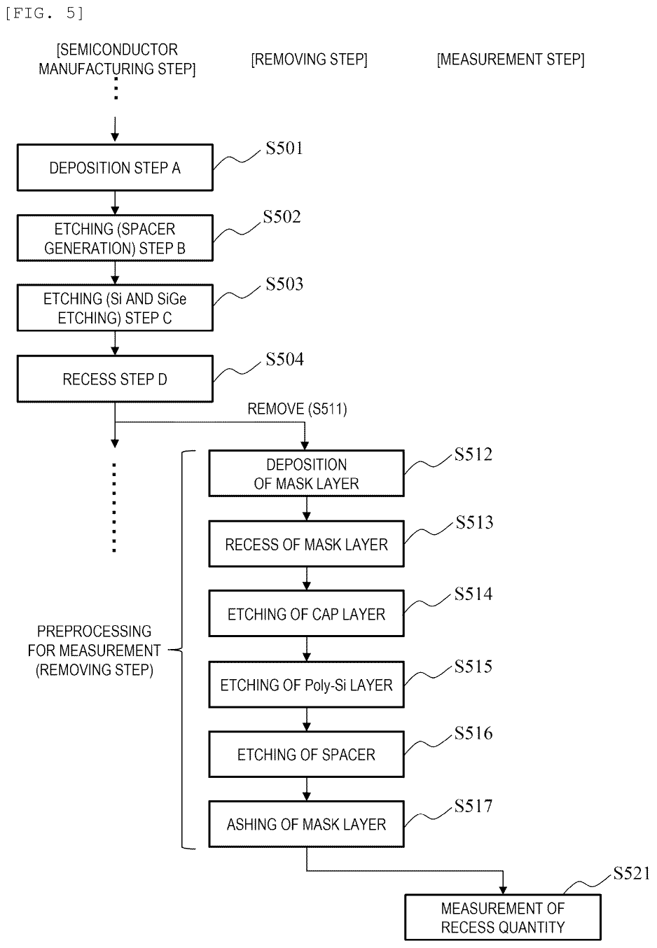

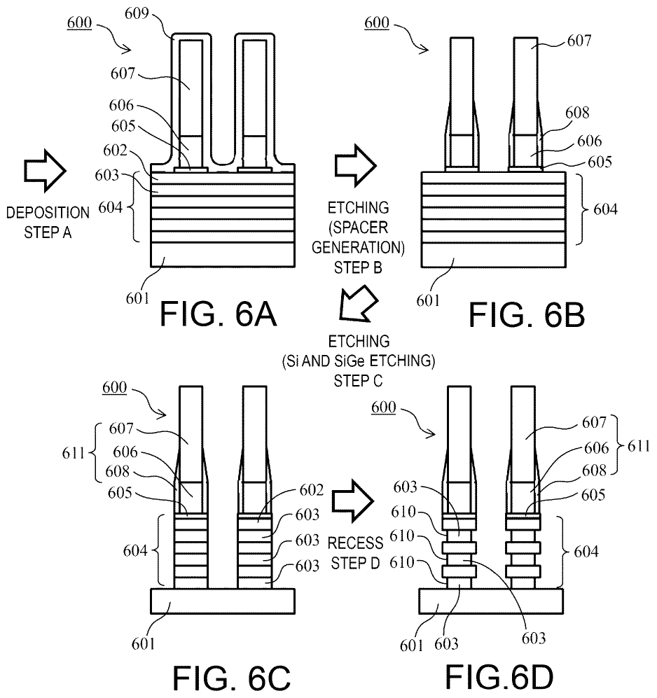

FIG. 5 is a flow chart illustrating a method for manufacturing a semiconductor device including a GAA structure and a method for removing an upper structure performed before measurement of the semiconductor device. FIGS. 6 to 8 are diagrams illustrating changes in a cross section of a product in a manufacturing process of the semiconductor device.

First, a method for manufacturing a Fin semiconductor device will be described with reference to FIGS. 5 and 6.

### Deposition Step A

First, a semiconductor device 600 including an impurity region 601, the Si and SiGe stacked layer 604 that is formed on the impurity region 601 and in which a Si layer 602 and a SiGe layer 603 are alternately stacked, a gate insulating film 605 formed on the Si and SiGe stacked layer 604, a Poly-Si layer 606 (polysilicon) formed on the gate insulating film 605, and a cap layer 607 (SiN) formed on the Poly-Si layer 606 is prepared. Then, a SiOCN layer 609 for forming a spacer 608 to be described later is deposited on a surface of the semiconductor device 600 (S501 in FIG. 5, and (a) of FIG. 6).

### Etching Step B

Next, the semiconductor device 600 having the SiOCN layer 609 deposited on the surface is etched to form the spacer 608 (S502 in FIG. 5, and (b) of FIG. 6).

### Etching Step C

After the spacer 608 is formed, the Si and SiGe stacked layer 604 is etched to form a Fin structure as illustrated in (c) of FIG. 6 (S503 in FIG. 5, and (c) of FIG. 6).

### Recess Step D

After a side wall of the Si and SiGe stacked layer 604 is exposed as illustrated in (c) of FIG. 6, the SiGe layers 603 are selectively etched to form recesses 610 (S504 of FIG. 5, (d) of FIG. 6). (d) of FIG. 6 is a view illustrating a cross section of the Fin semiconductor device 600 after the recesses 610 are formed.

In a GAA transistor, it is important to determine whether the recess 610 is properly formed in order to confirm whether the GAA transistor properly functions as a semiconductor element. However, as illustrated in FIG. 6, since the recess 610 is formed after an upper structure 611 (the Poly-Si layer 606, the cap layer 607, and the spacer 608) is formed, the upper structure 611 hinders measurement based on beam irradiation. The upper structure 611 is, for example, a dummy gate stacked body, and includes the Poly-Si layer 606, the cap layer 607 formed on the Poly-Si layer 606, and the spacer 608 serving as a side wall of the upper structure 611. Therefore, in the embodiment to be described below, a removal method for removing the upper structure 611 will be described as preprocessing for measurement.

### Method for Removing Upper Structure 611

Next, a method for removing the upper structure 611 (the dummy gate stacked body: Poly-Si layer 606, cap layer 607, and spacer 608) of the Fin semiconductor device 600 will be described with reference to FIGS. 5, 7, and 8.

First, a semiconductor wafer to be measured is removed from a semiconductor manufacturing step (S511).

### Deposition of Mask Layer

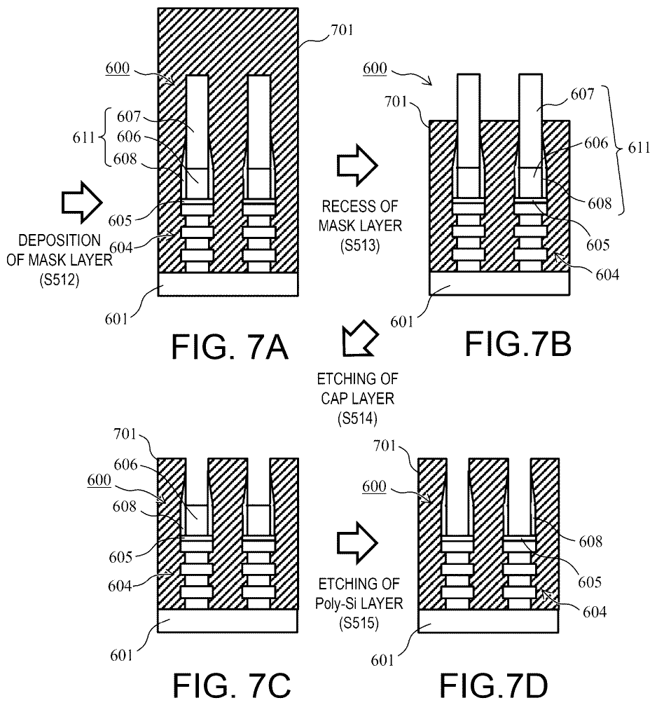

Then, a mask layer 701 is deposited on the semiconductor wafer using the film forming apparatus 108 (S512). (a) of FIG. 7 is a cross-sectional view illustrating the semiconductor device 600 after the mask layer 701 is deposited. The film forming apparatus 108 deposits the mask layer 701 under a film thickness condition set by the host computer 100 or the computer system 107 (computer or the like). The mask layer 701 is provided to protect the Si and SiGe stacked layer 604 together with the gate insulating film 605 in an etching or ashing step for removing the upper structure 611. Therefore, a surface of the mask layer 701 is formed higher than at least the Si and SiGe stacked layer 604.

### Recess of Mask Layer

Next, the mask layer 701 is recessed using the etching apparatus 109 (S513). (b) of FIG. 7 is a cross-sectional view illustrating the semiconductor device 600 in which a part of the mask layer 701 is recessed. In S513, the mask layer 701 is recessed under a condition that at least a part of the cap layer 607 is exposed and a surface of the mask layer 701 is positioned higher than an upper end portion of the spacer 608. The recess is formed under such a condition that the Fin (the Si and SiGe stacked layer 604) is hidden by the mask layer 701 when the Poly-Si layer 606 is removed which will be described later. In addition, since the mask layer 701 may retreat depending on selection of an etching rate at the time of removing a side wall, or the mask layer 701 may retreat at the time of removing the Poly-Si layer 606, a recess quantity may be selected in consideration of the retreat (so that the Fin is hidden even when the mask layer 701 retreats).

### Etching of Cap Layer

Next, the cap layer 607 is removed by etching using the etching apparatus 109 (S514). (c) of FIG. 7 is a cross-sectional view illustrating the semiconductor device 600 after the cap layer 607 is removed. Etching conditions for removing the cap layer 607 are stored in advance in a storage medium (not illustrated) incorporated in the computer system 107 that controls the etching apparatus 109.

### Etching of Poly-Si Layer

Next, the Poly-Si layer 606 is removed by etching using the etching apparatus 109 (S515). (d) of FIG. 7 is a cross-sectional view illustrating the semiconductor device 600 after the Poly-Si layer 606 is removed. Etching conditions for removing the Poly-Si layer 606 are stored in advance in a storage medium (not illustrated) incorporated in the computer system 107 that controls the etching apparatus 109.

### Etching of Spacer

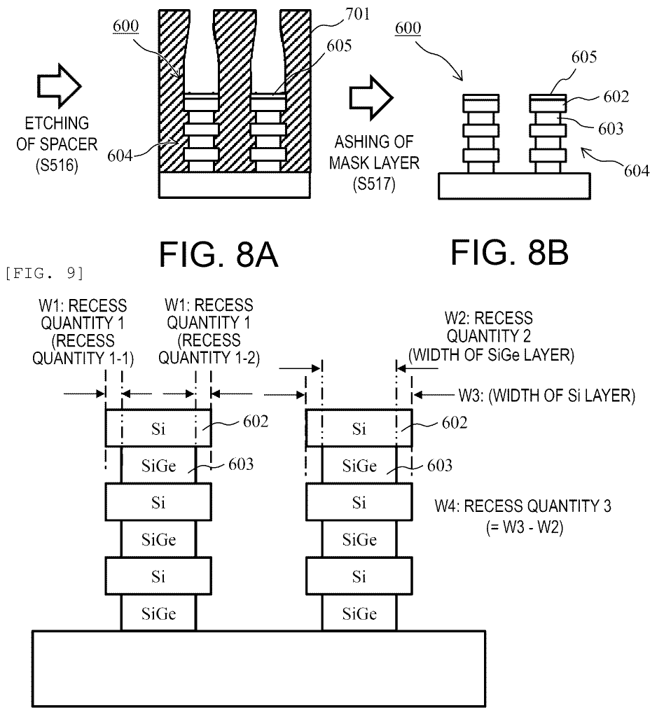

Next, the spacer 608 is etched by the etching apparatus 109 to remove the remaining spacer 608 (S516). (a) of FIG. 8 is a cross-sectional view illustrating the semiconductor device 600 after the spacer 608 is removed. When the spacer 608 is made of a SiN-based material such as SiN or SiOCN, dry etching using a CF-based gas containing oxygen or hydrogen, or a CHF-based gas containing oxygen, or wet etching using a hot phosphoric acid solution can be used.

### Ashing of Mask Layer

After removing the spacer 608, the mask layer 701 provided for the purpose of protecting the Si and SiGe stacked layer 604 is removed by ashing using the ashing apparatus 110 (S517). Accordingly, a side wall of the Si and SiGe stacked layer 604 can be exposed. (b) of FIG. 8 is a cross-sectional view illustrating the semiconductor device 600 after the mask layer 701 is removed. When the mask layer 701 is a resist or a carbon-based organic film, the mask layer 701 can be removed by performing ashing in an oxygen atmosphere at a high temperature (for example, about 300° C.).

A surface of the Si and SiGe stacked layer 604 is exposed by removing the upper structure 611 (the Poly-Si layer 606, the cap layer 607, and the spacer 608).

### Method for Measuring Semiconductor Device 600 (Recess Quantity of SiGe Layer 603)

In the present embodiment, the measurement apparatus 103 in which a recommended measurement condition to be described later is set irradiates the Si and SiGe stacked layer 604 from which the upper structure 611 was removed with an electron beam to measure a recess quantity of the SiGe layer 603 (S521). In this measurement step (S521), the Si and SiGe stacked layer 604 is irradiated with an electron beam having energy enough to pass through the Si layer 602 and the gate insulating film 605, so that the electron beam reaches the recesses. In this measurement step (S521), the recess quantity of the SiGe layer 603 is measured using the measurement apparatus 3.

### Recess Quantity

Here, details of the recess quantity will be described with reference to FIG. 9.

As illustrated in FIG. 9, a dimension W1 between one end of the Si layer 602 (a Si nanosheet) and one end of the recessed SiGe layer 603 may be defined as a recess quantity (a recess quantity 1). A dimension (a recess quantity 1-1) between one end of the Si layer 602 (a Si nanosheet) and one end of the recessed SiGe layer 603 and a dimension (a recess quantity 1-2) between the other end of the Si layer 602 (a Si nanosheet) and the other end of the recessed SiGe layer 603 may be managed as different recess quantities.

A width W2 of the SiGe layer 603 may be defined as a recess quantity (a recess quantity 2).

A difference W4 between a width W3 of the Si layer 602 and the width W2 of the SiGe layer 603 may be defined as a recess quantity (a recess quantity 3).

### Method for Measuring Recess Quantity

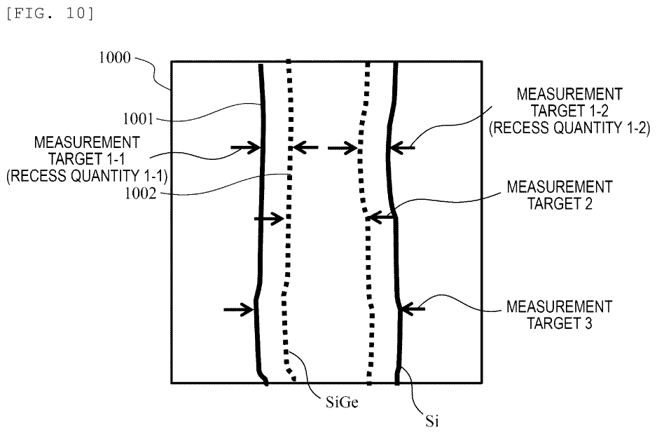

FIG. 10 is a schematic view illustrating an electron microscope image 1000 of the Si and SiGe stacked layer 604. Since secondary electrons are generated from the Si layer 602 when incident electrons (a primary electron beam) pass through the Si layer 602 and escape to a recess portion, the recess portion is displayed brighter than a portion of the Si and SiGe stacked layer 604. Therefore, when a luminance signal profile in an X direction is created and a width of a high-luminance region is measured, it is possible to measure all of the recess quantities 1 to 3 or any one of the recess quantities 1 to 3.

Further, a contour line between a high-luminance region and a low-luminance region may be extracted by binarization processing, segmentation, or the like on the electron microscope image 1000, and a dimension between contour lines may be measured. As described above, the recess quantity 1-1 and the recess quantity 1-2 may be evaluated by setting a dimension between an edge 1001 of the Si layer and an edge 1002 of the SiGe layer, that is, one recess and the other recess formed on left and right sides of the fin serving as a measurement target (a measurement target 1-1 and a measurement target 1-2).

A width of the edge 1002 of the SiGe layer, that is, a width of the SiGe layer (width of the edge 1002) may be used as a measurement target (a measurement target 2) to evaluate the recess quantity 2 (an etching condition).

Further, the recess quantity 3 may be evaluated by setting a width of the edge 1001 of the Si layer as a measurement target (a measurement target 3) and obtaining a difference between the measurement target 3 and the measurement target 2 (from the width of the edge 1002 of the SiGe layer).

It is possible to measure the recess quantities 1 to 3 with high accuracy by measuring the semiconductor device 600 from which the upper structure 611 was removed by the removing step as described above.

### Method for Recommending Measurement Condition

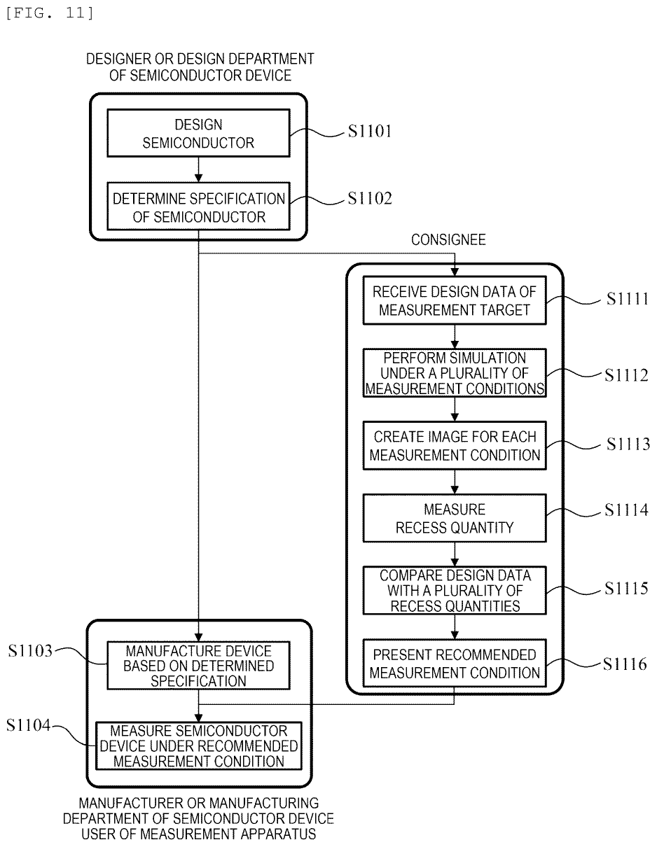

FIG. 11 is an example of a flow chart for presenting a recommended measurement condition recommended for use in the measurement apparatus 103 when a recess is measured. When the measurement apparatus 103 is a CD-SEM, there are many setting menus such as acceleration energy of an electron beam, a visual field size (magnification), a probe current, a scanning speed, and energy and an angle of a signal to be detected, and there are various combinations. It may be difficult to find an appropriate combination of measurement conditions from such many options.

A method for presenting a measurement condition recommended for use in the measurement apparatus 103 will be described below.

As illustrated in FIG. 11, a designer or a design department of the semiconductor device 600 designs the semiconductor device 600 including a GAA transistor and the like (S1101), and determines a specification (S1102). Design data of the semiconductor device 600 uses a predetermined format and includes three-dimensional information such as layout information and a film thickness.

The flow chart illustrated in FIG. 11 illustrates a workflow in which a consignee derives a measurement condition (an operation recipe of the measurement apparatus 103) recommended for use in the measurement apparatus 103 based on the design data of the semiconductor device provided from the designer or the design department of the semiconductor device 600, and provides the recommended measurement condition to a manufacturer or a manufacturing department (or a measurement department) of the semiconductor device 600. However, the present disclosure is not limited thereto, and a supplier or the like of the semiconductor device 600 having a simulator or the like may perform all the series of operations.

The consignee receives the design data including design information and specification information of the semiconductor device 600 (S1111). For example, the simulator 105 may receive the design data from a computer system of the designer or the design department of the semiconductor device via a network. The consignee may store the design data in a storage unit of the simulator 105, may store the design data in a storage medium of the host computer 100, or may store the design data in the design data storage medium 106.

The simulator 105 performs simulation based on the above-described design data (model data) and combination information (a plurality of measurement conditions) of a plurality of menus to be set in an electron microscope (S1112).

The simulation is performed using Monte Carlo simulation, an analysis method, a numerical analysis method, or the like. For example, the Monte Carlo simulation is a method for calculating a scattering process in a sample when the sample is irradiated with an electron beam using a Monte Carlo method (simulation using a random number) and calculating a distribution or a total number of secondary particles emitted from the sample. A simulated SEM image, a luminance profile, and the like are created by multiplying an energy and angle distribution of the emitted secondary particles by a detection acceptance. The Monte Carlo simulation has high accuracy and can reproduce an actual SEM image very well.

A graphics processing unit (GPU) may be mounted on the simulator 105 to speed up the Monte Carlo simulation. It is possible to shorten a calculation time while maintaining high accuracy by utilizing the GPU.

The analysis method is a method for creating a simulated SEM image by mathematically expressing a white band or a shadow with respect to a shape without considering scattering in a sample. How much an actual SEM image can be reproduced depends on accuracy of a formula. On the other hand, since the analysis method does not calculate a scattering process in the sample, a calculation time can be significantly shortened.

In the numerical analysis method, a distribution of the secondary particles emitted from a sample surface is assumed and made into a matrix, and the matrix, a matrix of shape data, and a matrix representing detection acceptance are multiplied to create a simulated SEM image.

The numerical analysis method can significantly shorten a calculation time as compared with the Monte Carlo simulation, but the calculation time is longer than that of the analysis method.

Although the above methods are described here, it is also possible to combine a method obtained by combining two of the methods, for example, using the Monte Carlo simulation for a portion having a large shape change and using the analysis method for other portions having a small shape change. As described above, there are various methods for creating the simulated SEM image, and any one of the methods may be used as long as the simulated SEM image can be created.

As described above, the simulator 105 creates an image (a simulated SEM image) for each different measurement condition using the Monte Carlo simulation or the like (S1113). Then, the simulator 105 transmits the created image to the host computer 100 or the computer system 107.

Since the image created by the simulation is luminance distribution information in units of pixels according to a detection amount of the secondary electrons or the backscattered electrons as in a normal SEM image, a luminance profile is created and measurement using the luminance profile is performed as in a length measurement method for an SEM image. The host computer 100 or the computer system 107 measures the measurement targets 1 to 3 (see FIG. 10) included in images corresponding to the plurality of setting menus (measurement conditions) received from the simulator 105, and calculates the recess quantities 1 to 3 (S1114). Alternatively, the simulator 105 may calculate the recess quantities 1 to 3.

When the recess quantities 1 to 3 obtained as described above match or are close to the original design data of the semiconductor device 600, it can be said that a setting menu (a measurement condition) defined in the simulation based on the recess quantities 1 to 3 is appropriate. Therefore, the host computer 100 compares the design data of the semiconductor device 600 with the recess quantities in a plurality of images formed based on the simulation using a plurality of setting menus (measurement conditions) as inputs (S1115).

Then, the host computer 100 selects a setting menu (a measurement condition) in which the calculated recess quantity is close to (highly correlated with) the specification of the semiconductor device from the plurality of setting menus, and presents the selected setting menu as a recommended measurement condition (S1116). For example, the host computer 100 may present the recommended measurement condition by displaying the recommended measurement condition on a display unit, or may transmit data indicating the recommended measurement condition to the computer system 107 of the measurement apparatus 103.

On the other hand, the designer or the design department of the semiconductor device 600 manufactures the semiconductor device based on the specification of the semiconductor device (S1103).

Then, a designer or a design department of the semiconductor device sets a recommended measurement condition in the measurement apparatus 103. The measurement apparatus 103 measures the semiconductor device 600 under the recommended measurement condition (S1104). The semiconductor device may be the semiconductor device 600 from which the upper structure 611 is removed by the removing step described above, or may be the semiconductor device 600 including the upper structure 611.

### Model Data

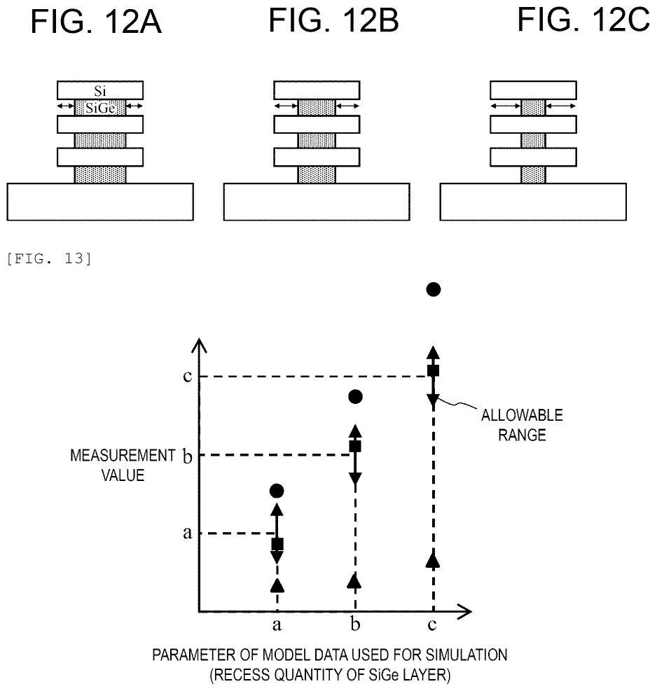

FIG. 12 is a diagram illustrating an example of model data used for simulation. FIG. 12 illustrates visualization of data related to the Si and SiGe stacked layer 604, which is provided to the simulator 105.

FIG. 12 illustrates three pieces of model data having different sizes (widths) of SiGe layers. It is possible to find a measurement condition that does not depend on the recess quantity by preparing model data having different recess quantities in this manner. When there is at least one model, a setting menu (a measurement condition) suitable for a specific size can be selected from different setting menus (measurement conditions).

### Method for Selecting Recommended Measurement Condition

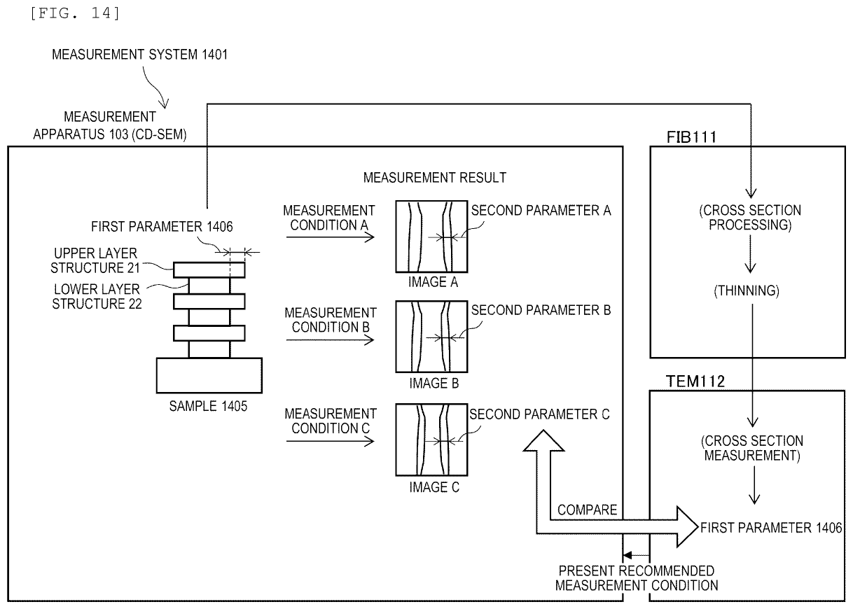

FIG. 13 is a graph illustrating a relationship between a parameter (a recess quantity of the SiGe layer) of model data used for simulation and measurement values obtained by measuring an image created based on the simulation.

FIG. 13 illustrates an example in which measurement results of images obtained by setting three measurement conditions (setting menus) are plotted. In the example of FIG. 13, the measurement values based on setting of the measurement condition 2 among the three measurement conditions indicates a value closer to a design value than the other measurement conditions. That is, the measurement condition 2 is appropriate for measurement of a recess quantity. As described above, by comparing the recess quantity of the design data (specification) with the measurement values of the images obtained by the simulation and selecting a measurement condition in which the measurement value is close to (highly correlated with) the design data, measurement can be performed under a condition suitable for measurement of the recess quantity created based on desired design data.

Although when a difference from the recess quantity of the design data is equal to or less than a predetermined value (within an allowable range), it is determined that the measurement condition is appropriate in the example of FIG. 13, the present disclosure is not limited thereto, and for example, in a case where inclination of a straight line when the measurement value for each measurement condition is linearly approximated satisfies a predetermined condition (for example, in a case where a difference in inclination from an ideal straight line is equal to or less than a predetermined value), it may be determined that the measurement condition is appropriate. Any type of determination method can be used as long as a measurement condition that outputs a measurement value closer to a design value than other measurement conditions can be selected.

Although when all the differences from the recess quantity of the design data of each model data are equal to or less than a predetermined value (within an allowable range), it is determined that the measurement condition is suitable in the example of FIG. 13, the present disclosure is not limited thereto, and a measurement condition in which the number of measurement values equal to or less than a predetermined value (within an allowable range) is the largest (highly correlated) may be set as a recommended measurement condition.

The recommended measurement condition determined as described above is presented to a user (a manufacturer, a manufacturing department, or the like of the semiconductor device) who actually measures the semiconductor device using the measurement condition. Specifically, a consignee creates a report indicating a basis for deriving a recommended measurement condition, such as a simulation condition, a pseudo SEM image, or the graph as illustrated in FIG. 13, together with the recommended measurement condition. At this time, a plurality of recommended measurement conditions may be presented.

A user who received the recommended measurement conditions as described above manufactures a semiconductor device based on design information of a design department, and measures the semiconductor device using a measurement apparatus in which the recommended measurement condition is set.

### Effects of Embodiment 1

According to the workflow as described above, a manufacturer or the like of the semiconductor device can optimize a measurement condition (an acceleration voltage, a focus, beam tilt, a detector position, and the like) for measuring a parameter (for example, a recess quantity of the SiGe layer) of a lower layer structure that cannot be directly observed and measured due to an upper structure (the Si layer 602, the upper structure 611, or the like) without requiring special knowledge and experience.

In Embodiment 1, since a recommended measurement condition is selected by simulation using the model data and the plurality of measurement conditions, it is not necessary to process a cross section of the Si and SiGe stacked layer 604. Therefore, the recommended measurement condition can be presented without damaging the Si and SiGe stacked layer 604.

### Embodiment 2

Outline of Measurement System 1401 for Semiconductor Device 2 and Measurement method for Semiconductor Device 2

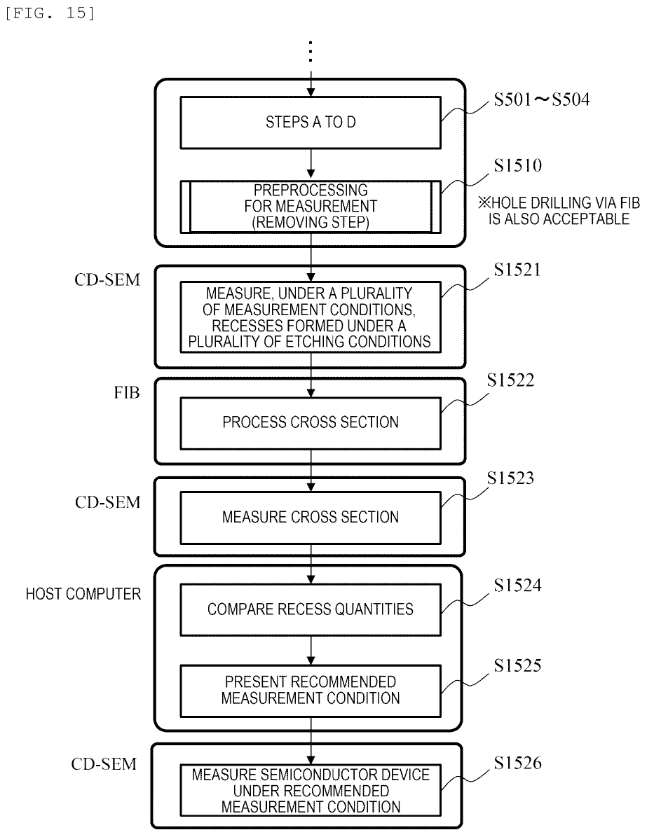

First, an outline of a measurement system 1401 for the semiconductor device 2 and a measurement method for the semiconductor device 2 according to Embodiment 2 will be described with reference to FIG. 14. The semiconductor device 2 to be measured is the same as that in Embodiment 1.

The measurement system 1401 includes the measurement apparatus 103 (for example, a CD-SEM) that measures the semiconductor device 2 by irradiating the semiconductor device 2 with the charged particle beam 31, the FIB apparatus 111 (a processing apparatus) that processes the semiconductor device, and the TEM 112 that measures the semiconductor device 2 processed by the FIB apparatus 111.

In Embodiment 2, first, a semiconductor device (a sample 1405) including the upper layer structure 21 and the lower layer structure 22 is prepared.

A plurality of measurement conditions (for example, measurement conditions A to C) used for measurement of the sample 1405 in the measurement apparatus 103 are prepared. These measurement conditions may be measurement conditions set by a skilled laboratory technician or the like based on past experience, or may be measurement conditions acquired or generated based on measurement history of the measurement apparatus 103.

The measurement apparatus 103 measures the sample 1405 under each of the plurality of prepared measurement conditions, acquires a measurement result (for example, images A to C) including at least one of an image or a signal waveform, and calculates a plurality of second parameters (second parameters A to C) corresponding to feature values (for example, recess quantities) of the lower layer structure 22 based on the image or the signal waveform.

On the other hand, the FIB apparatus 111 performs cross-section processing to expose a cross section of the sample 1405, and forms a thinned sample having the cross section.

Further, the TEM 112 measures the thinned sample and calculates a first parameter 1406 indicating a feature value (for example, a recess quantity) of the lower layer structure 22 based on an image (a cross-sectional measurement result) of the thinned sample.

For example, the host computer 100 compares the first parameter 1406 with the second parameters (the second parameters A to C), and presents a recommended measurement condition recommended for measuring the semiconductor device 2 among the plurality of measurement conditions. For example, when the second parameter B is closest to the first parameter 1406 among the second parameters A to C, the measurement condition B is presented to the measurement apparatus 103 as a recommended measurement condition.

### The Measurement Apparatus 103 Irradiates the

semiconductor device with the charged particle beam 31 according to the recommended measurement condition, acquires an image or a signal waveform, and calculates a feature value (for example, a recess quantity) of the lower layer structure 22 based on the image or the signal waveform.

Hereinafter, details of the measurement system 1401 according to Embodiment 2 will be described.

FIG. 15 is a flow chart illustrating a step of selecting an appropriate measurement condition using a plurality of GAA structures having different recess quantities actually generated under a plurality of etching conditions without using simulation or the like. As illustrated in FIGS. 5, 7, and 8, after the recesses are formed (after steps A to D), the upper structure 611 on the Si and SiGe stacked layer 604 is removed to a level at which the electron beam can reach the recess portions (S1510).

Here, in the removing step, sputtering processing by the FIB apparatus 111 may be performed, or chemical removal with a processing apparatus using a chemical reaction may be performed.

Next, the measurement apparatus 103 (the CD-SEM) performs, under a plurality of different measurement conditions, measurement on a plurality of samples formed under a plurality of etching conditions (S1521). Accordingly, a plurality of SEM images of each sample can be acquired. Then, a luminance profile is created based on these SEM images, measurement using the luminance profile is performed, and the recess quantities 1 to 3 are calculated based on the SEM images.

The FIB apparatus 111 performs cross-section processing on the plurality of samples ($1522).

Then, the measurement apparatus 103 measures cross sections of the samples ($1523). Accordingly, cross-sectional SEM images of a plurality of samples can be obtained.

Note that the FIB apparatus 111 may create a thinned sample having the cross section after processing the cross section of the sample, and the TEM 112 may measure the thinned sample to obtain cross-sectional TEM images.

The host computer 100 creates a luminance profile based on the cross-sectional SEM images, performs measurement using the luminance profile, and calculates the recess quantities 1 to 3 based on the cross-sectional SEM images. Then, the host computer 100 compares the recess quantities 1 to 3 calculated based on the cross-sectional SEM images with the recess quantities 1 to 3 calculated based on the SEM images in S1521 (S1524).

Then, the host computer 100 selects, from a plurality of setting menus (measurement conditions), a measurement condition in which recess quantities measured under the plurality of measurement conditions are close to the recess quantities 1 to 3 calculated based on the cross-sectional SEM images, and presents the selected measurement condition as a recommended measurement condition (S1525).

Then, a designer or a design department of the semiconductor device sets the recommended measurement condition in the measurement apparatus 103. The measurement apparatus 103 measures the semiconductor device 600 under the recommended measurement condition (S1526).

### Effects of Embodiment 2

It is possible to optimize a measurement condition (an acceleration voltage, a focus, beam tilt, a detector position, and the like) for measuring a parameter (for example, a recess quantity of the SiGe layer) of a lower layer structure that cannot be directly observed and measured due to an upper structure (the Si layer 602, the upper structure 611, or the like) without using the simulator 105 as in Embodiment 1.

Other effects are the same as those of Embodiment 1.

### Modification

The invention is not limited to the above-described embodiments and includes various modifications. For example, the above-described embodiments have been described in detail to facilitate understanding of the invention, and the invention is not necessarily limited to those including all the configurations described above. A part of a configuration of a certain embodiment can be replaced with a configuration of another embodiment, and a configuration of another embodiment can also be added to a configuration of a certain embodiment. In addition, another configuration can be added to, deleted from, or replaced with a part of a configuration of each embodiment.

### REFERENCE SIGNS LIST

1, 1401: measurement system
2: semiconductor device
3: measurement apparatus
4: simulator
5: model data
21: upper layer structure
22: lower layer structure
31: charged particle beam
51: first parameter
100: host computer
101: network
102: processing apparatus using chemical reaction (semiconductor manufacturing apparatus)
103: measurement apparatus
104: analysis system
105: simulator
106: design data storage medium
107: computer system
108: film forming apparatus
109: etching apparatus
110: ashing apparatus
111: FIB apparatus
112: TEM
301: electron source
302: extraction electrode
303: electron beam
304: condenser lens
305: scanning deflector
306: objective lens
307: sample chamber
308: sample stage
309: sample
310: electron
311: secondary electron
312: conversion electrode
313: detector
314: control device
315: A/D converter
316: image processing unit
317: CPU
318: image memory
320: workstation
401: processor
402: main storage unit
403: auxiliary storage unit
404: input and output I/F
600: semiconductor device
601: impurity region
602: Si layer
603: SiGe layer
604: Si and SiGe stacked layer
605: gate insulating film
606: Poly-Si layer
607: cap layer
608: spacer
609: SiOCN layer
610: recess
611: upper structure
701: mask layer
1405: sample
1406: first parameter

1. A semiconductor device measurement method for a semiconductor device including an upper layer structure constituting a part of the semiconductor device and a lower layer structure located below the upper layer structure, the semiconductor device measurement method comprising:
preparing model data that indicates the semiconductor device and in which a first parameter indicating a feature of the lower layer structure is known;
preparing a plurality of measurement conditions for a measurement apparatus that irradiates the semiconductor device with a charged particle beam to measure the semiconductor device;
performing simulation using the model data under each of the plurality of measurement conditions and acquiring a simulation result including at least one of an image or a signal waveform obtained when the semiconductor device represented by the model data is irradiated with the charged particle beam;
comparing the first parameter with each of a plurality of second parameters corresponding to features of the lower layer structure, the second parameters being respectively derived from a plurality of the simulation results; and
presenting a recommended measurement condition recommended for measuring the semiconductor device from among the plurality of measurement conditions based on comparison results between the first parameter and the second parameters.

2. The semiconductor device measurement method according to claim 1, wherein
the presenting the recommended measurement condition includes presenting, as the recommended measurement condition, a measurement condition having a highest correlation between the first parameter and the second parameter among the plurality of measurement conditions.

3. The semiconductor device measurement method according to claim 1, wherein
the preparing the model data includes preparing a plurality of pieces of model data having different first parameters, and
the acquiring the simulation result includes performing, for each of the plurality of pieces of model data, simulation using the model data under each of the plurality of measurement conditions and acquiring a plurality of simulation results for the plurality of pieces of model data, and
the comparing includes comparing, for each of the plurality of pieces of model data, the first parameter of the model data and each of the plurality of second parameters respectively derived from the plurality of simulation results of the model data.

4. The semiconductor device measurement method according to claim 1, wherein
the lower layer structure is processed after the upper layer structure is provided.

5. The semiconductor device measurement method according to claim 1, wherein
the semiconductor device is a semiconductor device in which the upper layer structure is a Si layer and the lower layer structure is a SiGe layer, and
the first parameter and the second parameter are parameters related to a recess of the SiGe layer relative to the Si layer.

6. A measurement system for measuring a semiconductor device including an upper layer structure constituting a part of the semiconductor device and a lower layer structure located below the upper layer structure, the measurement system comprising:
a measurement apparatus configured to irradiate the semiconductor device with a charged particle beam to measure the semiconductor device; and
a computer system including a processor and a memory, wherein
the computer system is configured to
store model data that indicates the semiconductor device and in which a first parameter indicating a feature of the lower layer structure is known,
store a plurality of measurement conditions for the measurement apparatus,
perform simulation using the model data under each of the plurality of measurement conditions and acquire a simulation result including at least one of an image or a signal waveform obtained when the semiconductor device represented by the model data is irradiated with the charged particle beam,
compare the first parameter with each of a plurality of second parameters corresponding to features of the lower layer structure, the second parameters being respectively derived from a plurality of the simulation results, and
present a recommended measurement condition recommended for measuring the semiconductor device from among the plurality of measurement conditions based on comparison results between the first parameter and the second parameters.

7. The measurement system according to claim 6, wherein
the computer system is configured to present, as the recommended measurement condition, a measurement condition having a highest correlation between the first parameter and the second parameter among the plurality of measurement conditions.

8. The measurement system according to claim 6, wherein
the computer system is configured to
store a plurality of pieces of model data having different first parameters,
perform, for each of the plurality of pieces of model data, simulation using the model data under each of the plurality of measurement conditions and acquire a plurality of simulation results for the plurality of pieces of model data, and
compare, for each of the plurality of pieces of model data, the first parameter of the model data and each of the plurality of second parameters respectively derived from the plurality of simulation results of the model data.

9. The measurement system according to claim 6, wherein
the lower layer structure is processed after the upper layer structure is provided.

10. The measurement system according to claim 6, wherein
the semiconductor device is a semiconductor device in which the upper layer structure is a Si layer and the lower layer structure is a SiGe layer, and
the first parameter and the second parameter are parameters related to a recess of the SiGe layer relative to the Si layer.

11. A semiconductor device measurement method for a semiconductor device including an upper layer structure constituting a part of the semiconductor device and a lower layer structure located below the upper layer structure, the semiconductor device measurement method comprising:
preparing a plurality of measurement conditions for a measurement apparatus that irradiates the semiconductor device with a charged particle beam to measure the semiconductor device;
acquiring a measurement result for each of the plurality measurement conditions by irradiating a sample of the semiconductor device with a charged particle beam, the measurement result including at least one of an image or a signal waveform of the sample;
measuring a cross section of the sample and acquiring a first parameter indicating a feature of the lower layer structure;
comparing the first parameter with each of a plurality of second parameters corresponding to features of the lower layer structure, the second parameters being respectively derived from a plurality of the measurement results; and
presenting a recommended measurement condition recommended for measuring the semiconductor device from among the plurality of measurement conditions based on comparison results between the first parameter and the second parameters.

12. The semiconductor device measurement method according to claim 11, wherein
the presenting the recommended measurement condition includes presenting, as the recommended measurement condition, a measurement condition having a highest correlation between the first parameter and the second parameter among the plurality of measurement conditions.

13. The semiconductor device measurement method according to claim 11, wherein
the lower layer structure is processed after the upper layer structure is provided.

14. The semiconductor device measurement method according to claim 11, wherein
the semiconductor device is a semiconductor device in which the upper layer structure is a Si layer and the lower layer structure is a SiGe layer, and
the first parameter and the second parameter are parameters related to a recess of the SiGe layer relative to the Si layer.

15. A measurement system for a semiconductor device including an upper layer structure constituting a part of the semiconductor device and a lower layer structure located below the upper layer structure, the measurement system comprising:
a measurement apparatus configured to irradiate the semiconductor device with a charged particle beam to measure the semiconductor device;
a processing apparatus configured to process the semiconductor device; and
a computer system including a processor and a memory, wherein
the measurement apparatus is configured to
store a plurality of measurement conditions for the measurement apparatus, and
acquire a measurement result for each of the plurality of measurement conditions by irradiating a sample of the semiconductor device with the charged particle beam, the measurement result including at least one of an image or a signal waveform of the sample,
the processing apparatus is configured to process the sample to expose a cross section of the sample, and
the computer system is configured to
compare a first parameter indicating a feature of the lower layer structure obtained from a cross section measurement result obtained by measuring the cross section of the sample with each of a plurality of second parameters corresponding to features of the lower layer structure, the second parameters being respectively derived from a plurality of the measurement results, and
present a recommended measurement condition recommended for measuring the semiconductor device from among the plurality of measurement conditions based on comparison results between the first parameter and the second parameters.

16. The measurement system according to claim 15, wherein
the computer system is configured to present, as the recommended measurement condition, a measurement condition having a highest correlation between the first parameter and the second parameter among the plurality of measurement conditions.

17. The measurement system according to claim 15, wherein
the lower layer structure is processed after the upper layer structure is provided.

18. The measurement system according to claim 15, wherein
the semiconductor device is a semiconductor device in which the upper layer structure is a Si layer and the lower layer structure is a SiGe layer, and
the first parameter and the second parameter are parameters related to a recess of the SiGe layer relative to the Si layer.
